(19) United States
(12) Patent Application Publication
(10) Pub. No.: US 2004/0038520 A1
(43) Pub. Date: Feb. 26, 2004

(54) Method of manufacturing semiconductor device

(76) Inventors: Masaharu Seto, Kanagawa (JP); Mie Matsuo, Kanagawa (JP)

Correspondence Address: Finnegan, Henderson, Farabow,, Garrett & Dunner, L.L.P., 1300 I Street, N.W., Washington, DC, 20005-3315, US

(21) Appl. No.: 10/394,154

(22) Filed: Mar. 24, 2003

(30) Foreign Application Priority Data
Mar. 29, 2002 (JP) 2002-095432

(51) Int. Cl. H01L 21/4763

(52) U.S. Cl. 438/637; 438/639

(57) ABSTRACT

A method of manufacturing a semiconductor device according to a first aspect of the present invention includes: forming a first photosensitive resin cured layer including a first opening above a semiconductor substrate, on which a underlying wiring layer is formed, the first opening being made above the underlying wiring layer; forming a second photosensitive resin cured layer including a second opening on the first photosensitive resin cured layer, a bottom of the second opening including an opening top of the first opening; and forming a wiring layer so as to fill in the first and second openings.

### CROSS-REFERENCE TO RELATED APPLICATIONS

This application is based upon and claims the benefit of priority from the prior Japanese Patent Application No. 2002-95432, filed on Mar. 29, 2002, the entire contents of which are incorporated herein by reference.

### BACKGROUND OF THE INVENTION

1. Field of the Invention

The present invention relates to a method of manufacturing a semiconductor device, particularly by using the dual damascene method in which a plug and a wiring are formed at a time.

2. Related Background Art

As the miniaturization of semiconductor devices advances, the thicknesses of interlayer dielectric films have become greater in recent years. In order to solve this problem, the dual damascene method has been employed to form a plug and a wiring to connect with the base wiring at a time.

A conventional method of forming a semiconductor device by the use of the damascene method will be described below with reference to FIGS. 6(a) to 6(f). As shown in FIG. 6(a), an interlayer dielectric film 5 is formed above a semiconductor substrate (not shown), on which a underlying wiring layer 4 is formed via an insulating layer 2. Then, a resist pattern 40, through which an opening 41 is made, is formed on the interlayer dielectric film 5 (FIG. 6(a)).

Subsequently, as shown in FIG. 6(b), the interlayer dielectric film 5 is patterned through anisotropic etching, using the resist pattern 40 as a mask, to form a groove 5a connecting to the underlying wiring layer 4 in the interlayer dielectric film 5. Thereafter, the resist pattern 40 is removed.

Then, as shown in FIG. 6(c), a resist pattern 44 for forming wiring is formed. Subsequently, a groove 5b, which is larger than the groove 5a, is formed through the interlayer dielectric film 5 through anisotropic etching, using the resist pattern 44 as a mask. Thereafter, the resist pattern 44 is removed.

Next, as shown in FIG. 6(d), a barrier metal layer 46 is formed over the entire surface. Thereafter, a metal layer 48 is deposited over the entire surface so as to fill in the grooves 5a and 5b, as shown in FIG. 6(e). Subsequently, the excessive metal is removed by CMP (Chemical Mechanical Polishing), etc., as shown in FIG. 6(f), thereby forming a wiring 48a which is integrated with a plug.

In the conventional manufacturing method shown in FIGS. 6(a) to 6(f), the etching process to form the wiring groove 5b is terminated before reaching the bottom of the insulating layer 5. Accordingly, the depth of the wiring groove 5b is depending only on the etching time calculated by the etching rate. Therefore, the depth of the wiring groove 5b is not accurately controlled.

Another conventional manufacturing method, in which the depth of the wiring groove 5b is accurately controlled, will be described below with reference to FIGS. 7(a) to 7(f).

First, as shown in FIG. 7(a), an interlayer dielectric film 61 formed of SiN, an interlayer dielectric film 62 formed of SiO₂, and an interlayer dielectric film 63 formed of SiN are sequentially formed above a semiconductor substrate (not shown), on which a underlying wiring layer 4 is formed via an insulating layer 2. Then, a resist pattern 70, through which an opening is made, is formed on the interlayer dielectric film 63.

Next, the interlayer dielectric film 63 is patterned through anisotropic etching using the resist pattern 70 as a mask, thereby forming an opening through the interlayer dielectric film 63. Then, the resist pattern 70 is removed. Subsequently, an interlayer dielectric film 72 of SiO₂ is formed so as to fill in the opening of the interlayer dielectric film 63 (FIG. 7(b)).

Thereafter, as shown in FIG. 7(c), a resist pattern 75 to be used for forming a wiring is formed. Subsequently, an opening 72a, the width of which is greater than that of the opening formed through the interlayer dielectric film 63, is formed through the interlayer dielectric film 72. Since the material of the interlayer dielectric film 62 is the same as that of the interlayer dielectric film 72, the interlayer dielectric film 62 is etched using the interlayer dielectric film 63 as a mask, thereby forming an opening 62a through the interlayer dielectric film 62, which has substantially the same width as the opening formed through the interlayer dielectric film 63. Subsequently, an opening 61a is formed through the interlayer dielectric film 61 through dry etching to expose the underlying wiring layer 4. Thereafter, the resist pattern 75 is removed.

Next, as shown in FIG. 7(d), a barrier metal layer 78 is formed over the entire surface. Then, as shown in FIG. 7(e), a metal layer 80 is deposited over the entire surface so as to fill in the opening. Subsequently, as shown in FIG. 7(f), the excessive metal is removed by CMP (Chemical Mechanical Polishing), etc. to form a wiring 80a which is integrated with a plug.

In the conventional method of manufacturing a semiconductor device shown in FIGS. 7(a) to 7(f), the depth of the opening 72a to be used for forming the wiring is determined by the thickness of the interlayer dielectric film 72. Accordingly, this depth can be accurately controlled. However, with respect to the opening to be used for forming a plug, the interlayer dielectric films 61, 62, and 63 formed under the interlayer dielectric film 72 should include a material which has a sufficiently high etch selectivity with respect to the material of the interlayer dielectric film 72. Accordingly, there are problems in that the selection of material is considerably limited, and that the increase in number of manufacturing steps results in the elongation of manufacturing time, thereby increasing the manufacturing cost.

### SUMMARY OF THE INVENTION

A method of manufacturing a semiconductor device according to a first aspect of the present invention includes: forming a first photosensitive resin cured layer including a first opening above a semiconductor substrate, on which a underlying wiring layer is formed, the first opening being made above the underlying wiring layer; forming a second photosensitive resin cured layer including a second opening on the first photosensitive resin cured layer, a bottom of the second opening including an opening top of the first opening; and forming a wiring layer so as to fill in the first and second openings.

A method of manufacturing a semiconductor device according to a second aspect of the present invention includes: forming an interlayer dielectric film above a semiconductor substrate, on which a underlying wiring layer is formed, so as to cover the underlying wiring layer; forming a first photosensitive resin cured layer including a first opening on the interlayer dielectric film, the first opening being made above the underlying wiring layer; forming a second photosensitive resin layer including a second opening on the first photosensitive cured layer, a bottom of the second opening including an opening top of the first opening; performing anisotropic etching on the interlayer dielectric film under the first opening, using the first photosensitive resin cured layer as a mask, and on the first photosensitive resin cured layer under the second opening, using the second photosensitive resin layer as a mask, in order to form a stepped opening; and removing the second photosensitive resin layer and forming a wiring layer so as to fill in the stepped opening.

### BRIEF DESCRIPTION OF THE DRAWINGS

FIGS. 1(a) to 1(d) are sectional views showing the process of manufacturing a semiconductor device according to the first embodiment of the present invention.

FIGS. 2(a) to 2(c) are sectional views illustrating in detail the formation of an upper photosensitive resin layer of the first embodiment.

FIG. 3 is a sectional view for explaining that the use of a positive polyimide to form the upper photosensitive resin layer may result in a problem.

FIGS. 4(a) to 4(d) are sectional views showing the process of manufacturing a semiconductor device according to a modification of the first embodiment.

FIGS. 5(a) to 5(f) are sectional views showing the process of manufacturing a semiconductor device according to the second embodiment of the present invention.

FIGS. 6(a) to 6(f) are sectional views showing a conventional method of manufacturing a semiconductor device.

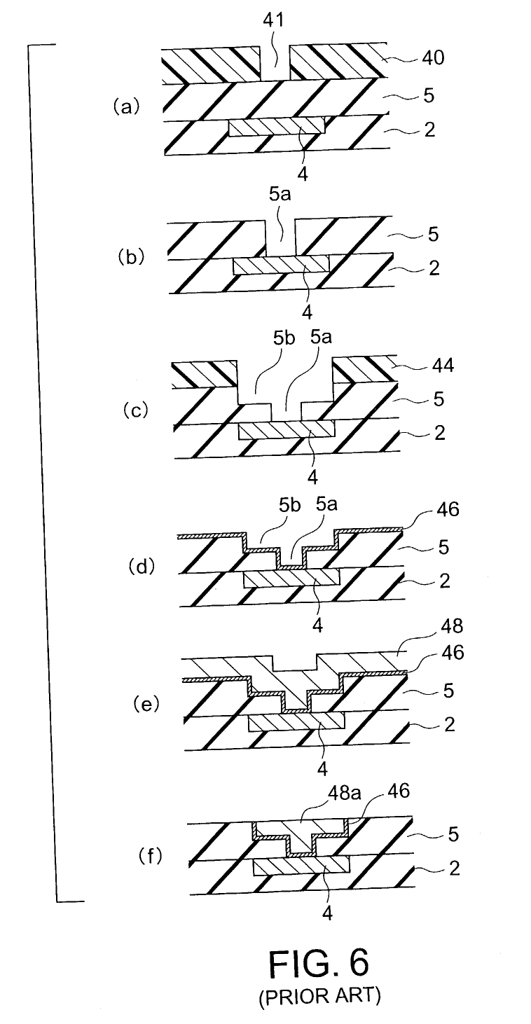

FIGS. 7(a) to 7(f) are sectional views showing another conventional method of manufacturing a semiconductor device.

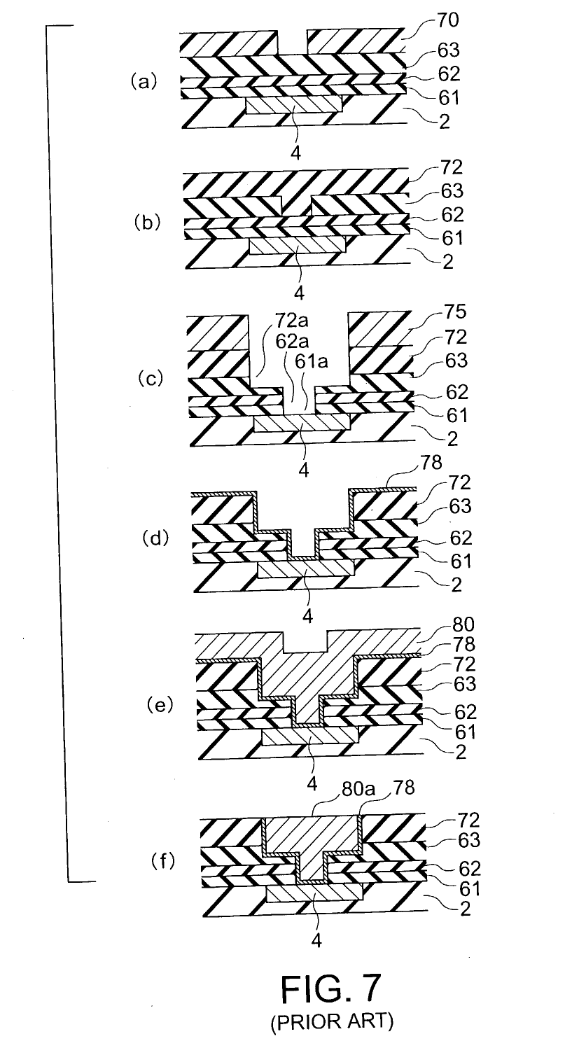

### DESCRIPTION OF THE EMBODIMENTS

Hereinafter, embodiments of the present invention will be specifically described with reference to the accompanying drawings.

(First Embodiment)

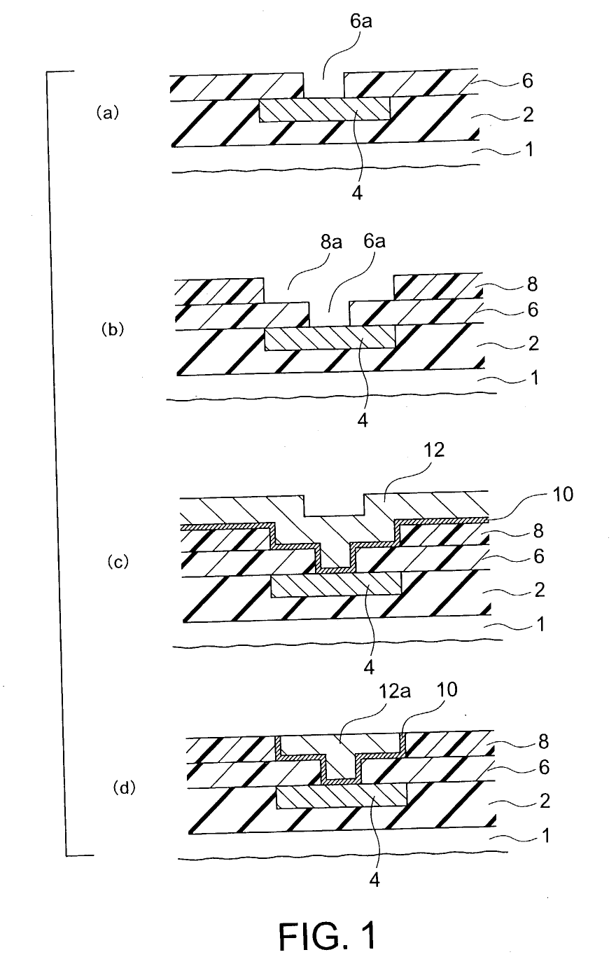

A method of manufacturing a semiconductor device according to the first embodiment of the present invention will be described below with reference to FIGS. 1(a) to 1(d), which are sectional views showing the process of manufacturing a semiconductor device according to the first embodiment.

First, as shown in FIG. 1(a), a semiconductor substrate 1, on which a underlying wiring layer 4 is formed via an interlayer dielectric film 2, is prepared, and a positive polyimide is applied thereto so as to have a predetermined thickness. Then, the semiconductor substrate is pre-cured at 120° C. and for four minutes. Thereafter, the semiconductor substrate is exposed in an i-line stepper using a desired mask, at an exposure dose of 550 mJ/cm², developed with a developer containing 2.38 wt % of TMAH (Tetramethyl Ammonium Hydroxide), and finally cured at 320° C. and for 60 minutes, thereby forming a photosensitive resin layer 6 having an opening 6a on the underlying wiring layer 4. Since the underlying wiring layer 4 is exposed before the formation of the photosensitive resin layer 6 in this embodiment, the underlying wiring layer 4 is still exposed at the bottom of the opening 6a.

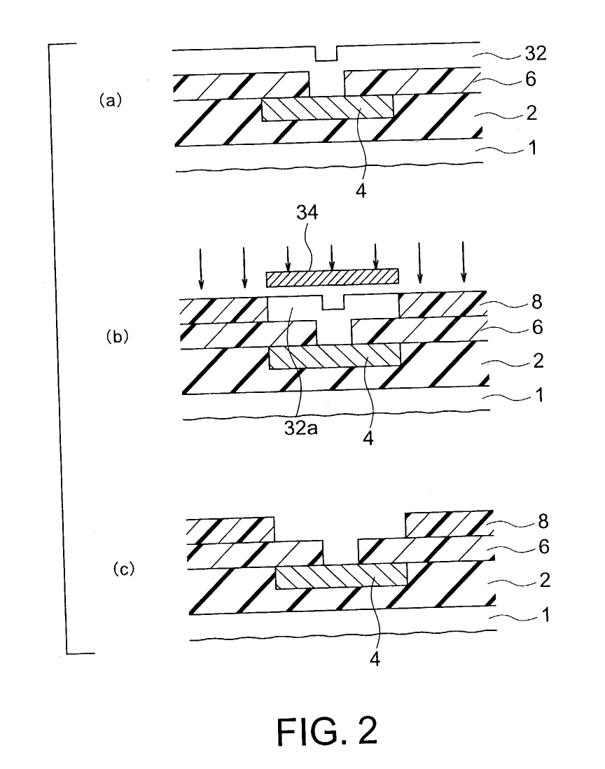

Subsequently, a photosensitive resin layer 8 having an opening 8a, which is larger than the opening 6a and the bottom of which includes the opening top of the opening 6a, is formed, as shown in FIG. 1(b). The photosensitive resin layer 8 is formed in the following manner. First, as shown in FIG. 2(a), a negative polyimide 32 is applied to the semiconductor substrate to have a predetermined thickness, and then the semiconductor substrate is pre-cured at 80° C. and for 10 minutes. Thereafter, as shown in FIG. 2(b), the semiconductor substrate is exposed in an i-line stepper at an exposure dose of 400 mJ/cm² using a desired mask 34. Then, the semiconductor substrate is developed by the use of a developer, thereby removing the unexposed portion 32a, and finally cured at 350° C. and for 90 minutes to form the photosensitive resin layer 8.

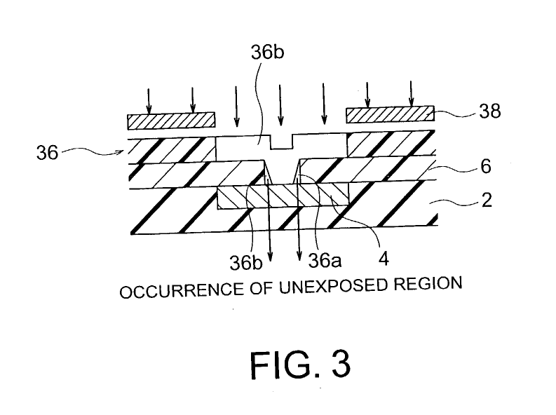

A problem, which may arise in the case where a positive polyimide is used for the formation of the photosensitive resin layer 8., will be described below with reference to FIG. 3. In such a case, after the photosensitive resin layer 6 having the opening 6a is formed, a positive polyimide 36 is applied to the semiconductor substrate so as to have a predetermined thickness. Then, the initial heating treatment is performed on the semiconductor substrate at a predetermined temperature. Thereafter, the semiconductor substrate is exposed by the use of a desired mask 38. As a result, sometimes there are regions, which are not exposed, at the side portions of the opening 6a of the photosensitive resin layer 6, as shown in FIG. 3, resulting in that some unexposed positive polyimide 36a may remain at the side portions of the opining 6a of the photosensitive resin layer 6. For this reason, it is preferable that a negative photosensitive resin is used to form the photosensitive resin layer 8. There will be no problem if a negative photosensitive resin is used instead of a positive polyimide to form the photosensitive resin layer 6. In FIG. 3, the reference numeral 36b denotes the exposed portion.

Next, as shown in FIG. 1(c), a TaN layer 10 serving as a barrier metal layer is formed over the entire surface of the sequentially formed photosensitive resin layers 6 and 8. Thereafter, a wiring material layer 12 of, e.g., Cu, is deposited, until the contact hole and the opening to form a wiring is filled in.

Subsequently, as shown in FIG. 1(d), the excessive portions of the TaN layer 10 and the wiring material layer 12, i.e., the portions besides the inside of the contact hole and the opening to form a wiring, are removed by CMP, thereby forming a wiring 12a which is integrated with a plug. If an upper layer wiring should be formed, the above-described process is repeated.

As described above, according to this embodiment, it is possible to accurately control the thickness of the wiring layer 12a and the depth of the plug by the thicknesses of the photosensitive resin layers 6 and 8. In addition, there is no limitation in the selection of material. For example, the etching selectivity between the photosensitive resin layers 6 and 8 is not required to be sufficiently high.

Moreover, since the interlayer dielectric film between the underlying wiring layer 4 and the wiring layer 12a is formed by using the two layers, i.e., the photosensitive resin layers 6 and 8, it is not necessary to use anisotropic etching. Accordingly, the manufacturing steps can be reduced, and the manufacturing time can be shortened as compared to the conventional cases. Therefore, the manufacturing cost can be decreased.

(Modification of First Embodiment)

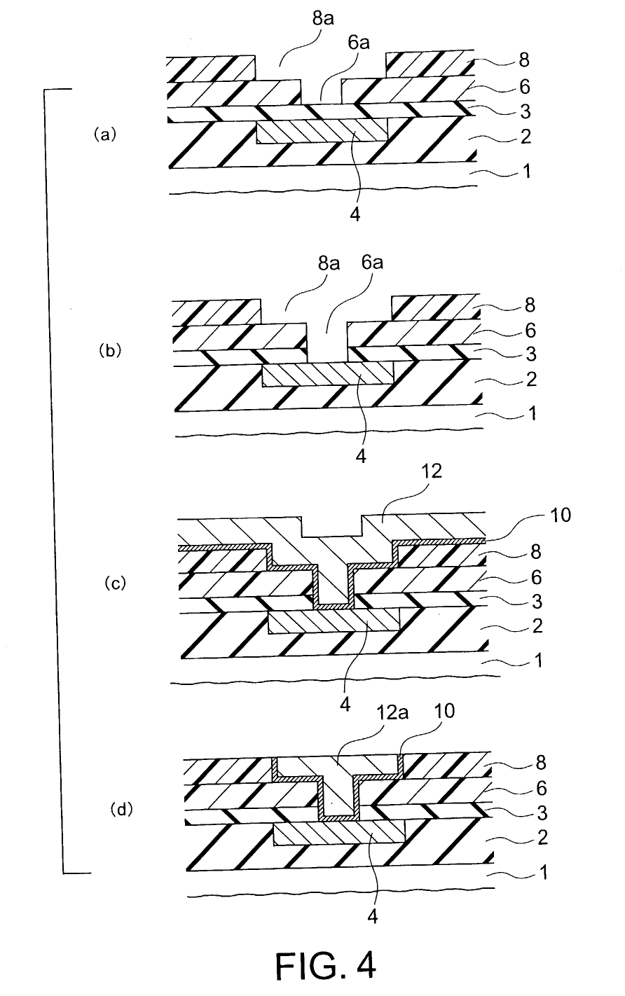

In the above-described first embodiment, the underlying wiring layer 4 is exposed before the formation of the photosensitive resin layer 6. A modification of the first embodiment will be described below, in which the underlying wiring layer 4 is not exposed, but is covered by an insulating layer formed of, e.g., SiN, with reference to FIGS. 4(a) to 4(d).

The process of manufacturing this modified example is the same as that of the first embodiment until the step shown in FIG. 1(b).

That is, a photosensitive resin layer 6 having an opening 6a and a photosensitive resin layer 8 having an opening 8a are formed on an insulating layer 3 of SiN. Accordingly, the insulating layer 3 formed of SiN is exposed at the bottom of the opening 6a (FIG. 4(a)). Thereafter, the exposed portion of the insulating layer 3 of SiN is etched and removed using the photosensitive resin layers 6 and 8 as masks (FIG. 4(b)). This etching process can be performed through the anisotropic etching. Subsequently, a barrier metal layer 10 is formed through the same process as shown in FIGS. 1(c) and 1(d) to form a wiring layer 12a (FIGS. 4(c) and 4(d)). The etching and removal of the insulating layer 3 of SiN can be performed immediately after the formation of the photosensitive layer 6 having an opening 6a.

In this modified example, it is also possible to accurately control the thickness of the wiring layer 12a and the depth of the plug in accordance with the thicknesses of the photosensitive resin layers 6 and 8. Further, the degree of freedom in the choice of the material of the photosensitive resin layers 6 and 8 is high.

Furthermore, in this modified example, the anisotropic etching is performed only once when the insulating layer of SiN is etched and removed. Accordingly, the number of the manufacturing steps can be decreased and the manufacturing time can be shortened as compared with the conventional cases. Therefore, the manufacturing cost can be reduced.

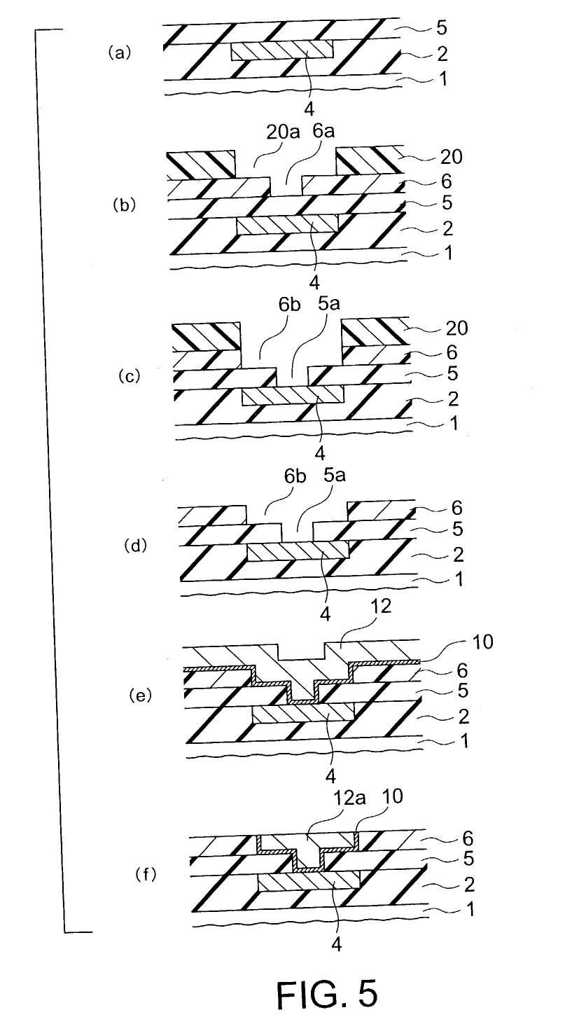

(Second Embodiment) p Next, a method of manufacturing a semiconductor device according to the second embodiment of the present invention will be described with reference to FIGS. 5(a) to 5(f), which are sectional views showing the process of manufacturing a semiconductor device according to the second embodiment.

First, as shown in FIG. 5(a), a interlayer dielectric film 5 is formed above a semiconductor substrate 1, on which a underlying wiring layer 4 is formed via an insulating layer 2. The material of the interlayer dielectric film 5 used here has a sufficiently high etching selectivity with respect to the material of the photosensitive resin layer to be formed thereon.

Next, as shown in FIG. 5(b), a photosensitive resin layer 6 having an opening 6a is formed on the underlying wiring layer 4. The photosensitive resin used here can be of either positive type or negative type used to form the photosensitive resin layers 6 and 8 of the first embodiment. Then, a photoresist pattern 20 having an opening 20a, which is larger than the opening 6a and the bottom of which includes the opening top of the opening 6a, is formed by using the photolithography technique.

Then, as shown in FIG. 5(c), the interlayer dielectric film 5 is etched through anisotropic etching using the photosensitive resin layer 6 as a mask, and the photosensitive resin layer 6 is etched through anisotropic etching using the photosensitive resin layer 6 as a mask, to form openings 5a and 6b for forming a plug and a wiring. The opening 6b is formed as an extension of the opening 5a. That is, the openings 5a and 6b are integrally formed as a stepped opening. The above-described anisotropic etching steps can be performed at a time by appropriately selecting the etching rate and the thicknesses of the photosensitive resin layer 6 and the interlayer dielectric film 5.

Subsequently, as shown in FIG. 5(d), the photoresist pattern 20 is removed. Thereafter, as shown in FIG. 5(e), a wiring material layer 12 is deposited over the entire surface so as to fill in the openings 6b and 5a via a TaN layer 10 serving as a barrier metal layer. Then, the excessive portions of the TaN layer 10 and the wiring material layer 12 are removed by CMP method, to form a wiring layer 12a which is integrated with a plug.

As described above, according to this embodiment, it is possible to accurately control the thickness of the wiring layer 12a and the depth of the plug in accordance with the thicknesses of the insulating layer 5 and the photosensitive resin layer 6. Further, since anisotropic etching is performed only once, the number of the manufacturing steps can be decreased and the manufacturing time can be shortened, thereby reducing the manufacturing cost.

(Modification of Second Embodiment)

In the above-described second embodiment, the underlying wiring layer 4 is exposed before the formation of the interlayer dielectric film 5. A modification of the second embodiment will be described below, in which the underlying wiring layer 4 is not exposed, but is covered by an insulating layer formed of, e.g., SiN.

The process of manufacturing this modified example is the same as that of the second embodiment until the step shown in FIG. 5(c).

That is, an interlayer dielectric film 5 having an opening 5a and a photosensitive resin layer 6 having an opening 6b are formed on an insulating layer of SiN. Accordingly, the insulating layer formed of SiN is exposed at the bottom of the opening 5a. Thereafter, the exposed portion of the insulating layer of SiN is etched and removed using the interlayer dielectric film 5 and the photosensitive resin layer 6 as masks. This etching process can be performed through the anisotropic etching. Subsequently, a barrier metal layer 10 is formed through the same process as shown in FIGS. 5(d), 5(e), and 5(f) to form a wiring layer 12a.

In this modified example, it is also possible to accurately control the thickness of the wiring layer 12a and the depth of the plug in accordance with the thicknesses of the interlayer dielectric film 5 and the photosensitive resin layer 6.

Furthermore, also in this modified example, the number of the manufacturing steps can be decreased and the manufacturing time can be shortened as compared with the conventional cases. Therefore, the manufacturing cost can be reduced.

As described above, according to the embodiments of the present invention, it is possible to reduce the manufacturing cost, and to accurately control the thickness of the wiring layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A method of manufacturing a semiconductor device comprising:
forming a first photosensitive resin cured layer including a first opening above a semiconductor substrate, on which a underlying wiring layer is formed, the first opening being made above the underlying wiring layer;
forming a second photosensitive resin cured layer including a second opening on the first photosensitive resin cured layer, a bottom of the second opening including an opening top of the first opening; and
forming a wiring layer so as to fill in the first and second openings.

2. The method of manufacturing a semiconductor device according to claim 1, further comprising forming a barrier metal layer to cover bottoms and side portions of the first and second openings before forming the wiring layer.

3. The method of manufacturing a semiconductor device according to claim 1, wherein the second photosensitive resin is of negative type.

4. The method of manufacturing a semiconductor device according to claim 1, further comprising:
forming an insulating layer on the underlying wiring layer before forming the first photosensitive resin cured layer; and
etching and removing the insulating layer under the first opening, using the first and second photosensitive resin cured layers as masks.

5. The method of manufacturing a semiconductor device according to claim 4, further comprising forming a barrier metal layer to cover bottoms and side portions of the first and second openings after etching and removing the insulating layer, and before forming the wiring layer.

6. The method of manufacturing a semiconductor device according to claim 1, wherein the first opening has a pattern which corresponds to a pattern of a plug of the wiring layer.

7. The method of manufacturing a semiconductor device according to claim 1, wherein the forming of the first photosensitive resin cured layer includes coating, exposing, developing, and curing the first photosensitive resin, and the forming of the second photosensitive resin cured layer includes coating, exposing, developing, and curing the second photosensitive resin.

8. The method of manufacturing a semiconductor device according to claim 7, wherein the coated first and second photosensitive resins are pre-cured before being exposed.

9. The method of manufacturing a semiconductor device according to claim 1, wherein a polyimide is used as the material of the first and second photosensitive resins.

10. The method of manufacturing a semiconductor device according to claim 1, wherein the forming of the wiring layer comprises:
depositing a wiring material above the first and second photosensitive resin cured layers including the first and second openings, and
removing the wiring material outside the first and second openings by chemical mechanical polishing until the second photosensitive resin cured layer is exposed.

11. A method of manufacturing a semiconductor device comprising:
forming an interlayer dielectric film above a semiconductor substrate, on which a underlying wiring layer is formed, so as to cover the underlying wiring layer;
forming a first photosensitive resin cured layer including a first opening on the interlayer dielectric film, the first opening being made above the underlying wiring layer;
forming a second photosensitive resin layer including a second opening on the first photosensitive cured layer, a bottom of the second opening including an opening top of the first opening;
performing anisotropic etching on the interlayer dielectric film under the first opening, using the first photosensitive resin cured layer as a mask, and on the first photosensitive resin cured layer under the second opening, using the second photosensitive resin layer as a mask, in order to form a stepped opening; and
forming a wiring layer so as to fill in the stepped opening after removing the second photosensitive resin layer.

12. The method of manufacturing a semiconductor device according to claim 11, further comprising forming a barrier metal layer to cover a bottom and side portions of the stepped opening before forming the wiring layer.

13. The method of manufacturing a semiconductor device according to claim 11, wherein the interlayer dielectric film has a sufficiently high etch selectivity with respect to the first photosensitive resin.

14. The method of manufacturing a semiconductor device according to claim 11, further comprising:
forming an insulating layer on the underlying wiring layer before forming the interlayer dielectric film; and
etching and removing the insulating layer under the stepped opening, using the first photosensitive resin cured layer and the interlayer dielectric film as masks.

15. The method of manufacturing a semiconductor device according to claim 14, further comprising forming a barrier metal layer to cover a bottom and side portions of the stepped opening after etching and removing the insulating layer and before forming the wiring layer.

16. The method of manufacturing a semiconductor device according to claim 11, wherein the first opening has a pattern which corresponds to a pattern of a plug of the wiring layer.

17. The method of manufacturing a semiconductor device according to claim 11, wherein the forming of the first photosensitive resin cured layer includes coating, exposing, developing, and curing the first photosensitive resin.

18. The method of manufacturing a semiconductor device according to claim 17, wherein the coated first photosensitive resin is pre-cured before being exposed.

19. The method of manufacturing a semiconductor device according to claim 11, wherein a polyimide is used as the material of the first photosensitive resin.

20. The method of manufacturing a semiconductor device according to claim 11, wherein the forming of the wiring layer comprises:
depositing a wiring material above the first photosensitive resin cured layer and the interlayer dielectric layer including the stepped opening, and
removing the wiring material outside the stepped opening by chemical mechanical polishing until the first photosensitive resin cured layer is exposed.
